(19) United States
(12) Patent Application Publication
(10) Pub. No.: US 2017/0157911 A1
(43) Pub. Date: Jun. 8, 2017

(54) METHODS AND APPARATUS FOR BONDING AND DE-BONDING A HIGHLY FLEXIBLE SUBSTRATE TO A CARRIER

(71) Applicant: Corning Incorporated, Corning, NY (US)

(72) Inventors: Bokyung Kong, Hwasung-si (KR); Kyungwook Park, Seoul (KR)

(21) Appl. No.: 15/364,876

(22) Filed: Nov. 30, 2016

(30) Foreign Application Priority Data
Dec. 3, 2015 (KR) 2015171575A

(51) Int. Cl. B32B 38/18; B32B 37/00; B32B 17/00

(52) U.S. Cl. CPC B32B 38/1858; B32B 17/00; B32B 37/0046; H01L 51/0097

(57) ABSTRACT

Methods and apparatus for bonding and/or de-bonding a flexible substrate to/from a carrier substrate include: moving a first plate, which supports a carrier substrate, relative to a second plate, which hold and releases a flexible substrate, in order to bond and/or de-bond the flexible substrate to/from the carrier substrate.

### CROSS-REFERENCE TO RELATED APPLICATIONS

This application claims the benefit of priority under 35 U.S.C. §119 of Korean Patent Application Serial No. 2015171575A filed on Dec. 3, 2015 the contents of which are relied upon and incorporated herein by reference in their entirety as if fully set forth below.

### BACKGROUND

The present disclosure relates to methods and apparatus for processing a flexible substrate, such as a highly flexible substrate, using so-called sheet manufacturing techniques, which are designed for thicker and stiffer substrates.

Sheet manufacturing techniques are typically employed to process respective substrates (e.g., glass sheets) by conveying the respective sheets from a source, through any number of processing steps (heating, scoring, trimming, cutting, etc.), to a destination. The conveyance of the respective sheets may involve a number of elements that cooperate to move the respective substrates from station to station, preferably without degrading any desirable characteristics of the substrates. For example, typical transport mechanisms may include any number of noncontact support members, contact support members, rollers, lateral guides, etc., to guide the substrates through the system from the source, through each process station, and finally to the destination. The non-contact support members may include air bearings, fluid bar(s), low friction surface(s), etc. Non-contact air bearings may include a combination of positive and negative fluid pressure streams in order to “float” the substrates during conveyance. Contact support elements may include rollers to stabilize the substrates during transport through the system.

The aforementioned transport mechanisms for sheet manufacturing systems are typically designed for relatively thick substrates, such as thicknesses that exhibit a sufficient stiffness to retain suitable mechanical dimensionality, material integrity, and/or other properties despite the forces that may be inflicted on the substrates during conveyance and processing through the manufacturing system. For example, typical sheet manufacturing techniques for cover glass used in liquid crystal displays (or other similar applications) require that the glass substrates exhibit a relatively high stiffness, such as may be the case when the substrates have thicknesses on the order of about 0.5 mm or greater.

Use of these sheet manufacturing techniques may become problematic, however, when substrates having significantly lower thickness and/or stiffness (e.g., highly flexible glass substrates) are processed.

At least some of the problems that might arise using conventional sheet manufacturing techniques on highly flexible substrates may be overcome by designing specialized processing equipment for conveying and processing such highly flexible substrates. The design of new, specialized processing equipment, however, would require significant non-recurring expense in terms of time and resources, as well as rendering existing (and possibly fully paid for) production equipment obsolete. For example, when processing highly flexible substrates, the conventional sheet manufacturing techniques may be discarded in favor of a “roll-to-roll” conveyance and processing equipment. In principle, such a substitution might lead to lower manufacturing costs in the long term; however, the non-recurring expense to design and implement a new roll-to-roll system for highly flexible substrate material would be very significant, and possibly require innovation to process certain types of flexible substrates.

While the above problems concerning the processing of highly flexible substrates have been recognized in the art and solutions have been investigated. It has been discovered that there remain needs in the art for new methods and apparatus for modifying flexible substrates such that they may be processed using sheet processing techniques.

### SUMMARY

For purposes of discussion, the disclosure herein may often refer to methodologies and apparatus involving substrates formed from glass; however, skilled artisans will realize that the methodologies and apparatus herein apply to substrates of numerous kinds, including glass substrates, crystalline substrates, single crystal substrates, glass ceramic substrates, polymer substrates, etc.

For example, one type of flexible substrate material is referred to as Corning® Willow® Glass, which is a glass material suitable for many purposes. The relatively thin material (about 0.1 mm thick, which is approximately the thickness of a sheet of paper), combined with the strength and flexibility of the glass material, support applications from the conventional to the highly sophisticated, such as wrapping a display element around a device or structure. Corning® Willow® Glass may be used for very thin backplanes, color filters, etc., for both organic light emitting diodes (OLED) and liquid crystal displays (LCD), such as may be used in high performance, portable devices (e.g., smart phones, tablets, and notebook computers). Corning® Willow® Glass may also be used for producing electronic components, such as touch sensors, seals for OLED displays and other moisture and oxygen sensitive technologies. Corning® Willow® Glass may be on the order of about 100 μm to 200 μm thick, and highly flexible, having glass characteristics including: a density of about 2.3-2.5 g/cc, Young's Modulus of about 70-80 GPa, Poisson Ratio of about 0.20-0.25, and minimum bend radius of about 185-370 mm.

If respective substrates of Corning® Willow® Glass were processed using conventional sheet manufacturing techniques (which are designed for thicker and stiffer substrates), the thinness and flexibility of the material would likely result in degradation of the material characteristics of the glass, critical failure of the glass, and/or interruption or damage to the sheet processing equipment.

The disclosure herein addresses the problems of processing flexible substrates, such as thin and flexible glass substrates, in existing sheet manufacturing systems (which are designed for thicker, stiffer substrates). In particular, the methods and apparatus herein provide for temporarily bonding the flexible substrate to a thicker and/or stiffer carrier substrate, which presents the flexible substrate as having the stiffer mechanical characteristics of the carrier, while being processed in the sheet processing system. After processing, the temporary bond is released and the flexible substrate is subject to further manufacturing, processing, or delivery to a customer.

Notably, while the concept of temporarily bonding the flexible substrate to a thicker and/or stiffer carrier substrate has been considered in the art, it has been discovered that the focus of previous investigations appears to have been primarily on the boding process. For example, one important characteristic of the temporary bond should be minimization of air bubbles between the substrates. Another important characteristic of the de-bonding process should be controlled separation of the substrates and minimization of any undesirable characteristics inflicted on the flexible substrate during same. The embodiments herein, however, consider a complimentary process focusing on both the characteristics of the temporary bonding process and the subsequent de-bonding of the highly flexible substrate.

Other aspects, features, and advantages will be apparent to one skilled in the art from the description herein taken in conjunction with the accompanying drawings.

### DESCRIPTION OF THE DRAWINGS

For the purposes of illustration, there are forms shown in the drawings that are presently preferred, it being understood, however, that the embodiments disclosed and described herein are not limited to the precise arrangements and instrumentalities shown.

FIG. 1 is a perspective view, schematic illustration of a mechanism in which a flexible substrate is bonded to a carrier substrate in preparation for processing the flexible substrate in a conventional sheet manufacturing system;

FIG. 2 is a side view, schematic illustration of the flexible substrate bonded to the carrier substrate for processing the flexible substrate in the conventional sheet manufacturing system;

FIG. 3 is a perspective view, schematic illustration of a bonding front propagating during a sequence in which the flexible substrate is bonded to the carrier substrate;

FIG. 4 is a schematic representation of a tool operative to both bond the flexible substrate to the carrier substrate, and thereafter, de-bond the flexible substrate from the carrier substrate;

FIGS. 5-10 illustrate two separate process sequences, the first sequence is a bonding sequence in which the tool is employed to bond the flexible substrate to the carrier substrate as illustrated by viewing FIGS. 5, 6, 7, 8, 9, and 10 in order, and the second sequence is a de-bonding sequence in which the tool is employed to de-bond the flexible substrate from the carrier substrate as illustrated by viewing FIGS. 10, 9, 8, 7, 6, and 5 in order;

FIG. 11 is a graphical illustration of a qualitative result of manually bonding the flexible substrate to the carrier substrate; and

FIG. 12 is a graphical illustration of a qualitative result of bonding the flexible substrate to the carrier substrate using the tool.

### DETAILED DESCRIPTION OF THE PREFERRED EMBODIMENTS

As mentioned previously, embodiments disclosed herein relate tot temporarily bonding a flexible substrate to a thicker and/or stiffer carrier substrate, processing the combined structure, and subsequently de-bonding the flexible substrate from the carrier substrate. While this general process has been investigated previously, it appears that the focus of such investigations has been primarily on the boding process. The embodiments herein, however, consider a complimentary process focusing on both the temporary bonding and the subsequent de-bonding of the highly flexible substrates.

For purposes of discussion, the embodiments discussed below refer to the processing of a flexible substrate formed from glass, which is a preferred material. It is noted, however, that the embodiments may employ different materials to implement the flexible substrate, such as crystalline substrates, single crystal substrates, glass ceramic substrates, polymer substrates, etc.

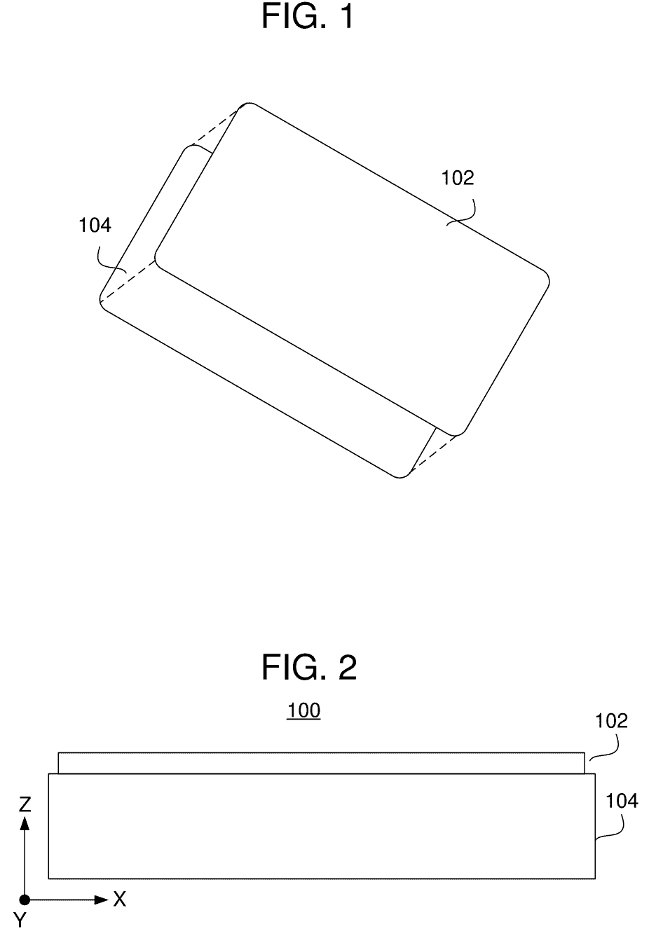

Reference is now made to FIG. 1, which is a perspective view, schematic illustration of a process in which a flexible substrate 102 is temporarily bonded to a carrier substrate 104 in preparation for processing the flexible substrate 102 in a conventional sheet manufacturing system. As mentioned previously, the rationale for bonding the flexible substrate 102 to the thicker and/or stiffer carrier substrate 104 is to present the flexible substrate 102 as if it had the stiffer mechanical characteristics of the carrier 104 while being processed in the conventional sheet processing system, which again is designed for handling stiffer substrates than the flexible substrate 102.

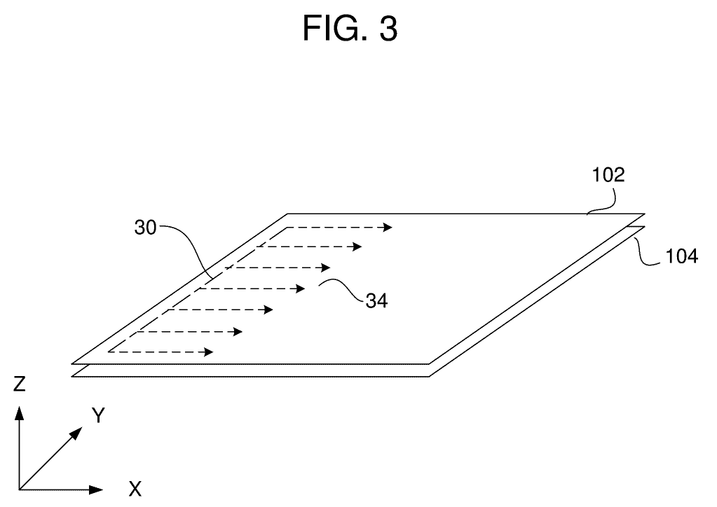

With reference to FIG. 2, a schematic illustration of the resulting bonded structure 100 (the flexible substrate 102 atop the carrier substrate 104) is shown. In this regard, the carrier substrate 104 may be formed from a sheet of material, such as a glass material, where the carrier substrate 104 has a length dimension along the X-axis, a width dimension along the Y-axis, and a thickness dimension along the Z-axis (within the illustrated Cartesian Coordinate System). Notably, the X-axis and Y-axis define an X-Y plane, which may be referred to herein as being in-plane and/or defining an in-plane reference.

Similarly, the flexible substrate 102 is formed from a sheet of material, which may also be a glass material, where the flexible substrate 102 has a length dimension in the X-axis, a width dimension in the Y-axis, and a thickness dimension in the Z-axis. As previously discussed, the flexible substrate 102 exhibits at least one of: (i) a flexibility that is substantially more flexible than a flexibility of the carrier substrate 104, and (ii) a thickness that is substantially less than a thickness of the carrier substrate 104.

In one or more embodiments, the flexible substrate 102 may be formed from glass and have a thickness of one of: (i) from about 50 um (microns or micrometers) to about 300 um, and (ii) from about 100 um to about 200 um. In accordance with one or more further embodiments, the flexible substrate 102 may have at least one of: a density of about 2.3-2.5 g/cc, a Young's Modulus of about 70-80 GPa; a Poisson Ratio of about 0.20-0.25, and a minimum bend radius of about 185-370 mm.

Similarly, in one or more embodiments, the carrier substrate 104 may be formed from glass; however, the carrier substrate 104 preferably has a thickness of one of at least from about 400 to about 1000 um, notably thicker than the flexible substrate 102. Additionally and/or alternatively, the carrier substrate 104 may be formed from a material having a substantially higher stiffness than the flexible substrate 102.

The bond between the flexible substrate 102 and the carrier substrate 104 is temporary, and employed primarily for the purpose of processing the flexible substrate 102 in a conventional sheet manufacturing system. After such processing, the temporary bond may be undone and the flexible substrate 102 may be separated from the carrier substrate 104 for further processing and/or application outside the conventional sheet manufacturing system. The embodiments herein are directed to the apparatus and methodologies for placing the flexible substrate 102 into position with respect to the carrier substrate 104, the contact of the substrates 102, 104 to facilitate the temporary bond, and the subsequent de-bonding and separation of the substrates 102, 104.

Any number of approaches for achieving the bonding attraction between the flexible substrate 102 and the carrier substrate 104 may be employed. By way of example, one skilled in the art may employ and/or modify one or more of the specific bonding techniques disclosed in the following patent applications in achieving the conditions disclosed herein: U.S. Provisional Patent Application No. 61/736,887, filed on Dec. 13, 2012; U.S. patent application Ser. No. 14/047,506, filed on Oct. 7, 2013; U.S. Provisional Patent Application No. 61/931,924 filed on Jan. 27, 2014; U.S. Provisional Patent Application No. 61/931,912, filed on Jan. 27, 2014; U.S. Provisional Patent Application No. 61/931,927 filed on Jan. 27, 2014; and U.S. Provisional Patent Application No. 61/977,364 filed on Apr. 9, 2014, the entire disclosures of which are hereby incorporated by reference.

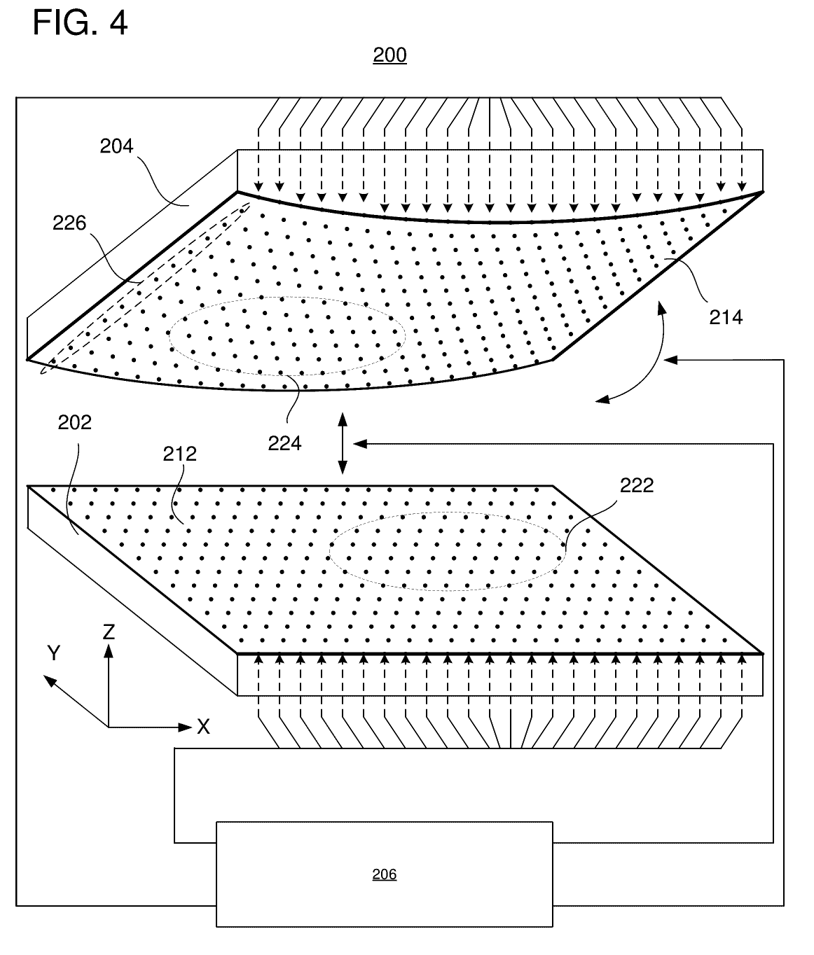

In order to more fully appreciate the advantages of the methods and apparatus disclosed herein, a detailed discussion of a generalized bonding process will be now be presented with reference to FIG. 3. In connection with this generalized process, it is assumed that the flexible substrate 102 is placed on the carrier substrate 104 and then bonded thereto. In this regard, FIG. 3 is a perspective view, schematic illustration of a bond front propagating during a sequence in which the flexible substrate 102 is bonded to the carrier substrate 104. For purposes of clarity and presenting background discussion, a specific mechanism for inducing the bond front is not presented at this time; however, specific embodiments for producing and controlling the bond front will indeed be presented later herein.

The generalized bonding process may include locating the flexible substrate 102 over the carrier substrate 104 and then inducing the bond therebetween. Again, the flexible substrate 102 and the carrier substrate 104 are characterized by respective length dimensions in the X-axis, respective width dimensions in the Y-axis, and respective thickness dimensions in the Z-axis. The X-axis and Y-axis thereby define an X-Y plane, which is an in-plane reference (against which a flatness of the bonded structure 100 may be compared). When the flexible substrate 102 is located over the carrier substrate 104 there will typically be some atmospheric gas (such as air) that maintains some relatively small separation between the substrates 102, 104. In order to initiate the bond, a start area 30 may be established by a localized urging of the flexible substrate 102 and the carrier substrate 104 together, such as via a mechanical pressing force. In the illustrated example, the start area 30 is a generally linearly extending start area established by way of a linearly extending focused pressure of the flexible substrate 102 toward, and into contact with, the carrier substrate 104. As noted above, one or more specific implementations for producing the linearly extending pressure and resultant linearly directed and extending start area 30 will be discussed in more detail later herein.

In the case of the illustrated example, a bond front 34 will include linearly directed vectors extending transversely away from the elongate direction of the start area 30, in the X-Y plane. For example, the start area 30 may extend substantially linearly along a line parallel to the Y-axis (such as along adjacent edges of the respective substrates 102, 104 shown at the left of FIG. 3). As a result, the bond front 34 has been found to include vectors that are spaced substantially linearly along a line parallel to the Y-axis (such as the line 30), and propagate away from the start area 30 in a direction transverse to the Y-axis (e.g., in a direction parallel to the X-axis, perpendicular to the Y-axis). The bond front 34 will continue to expand linearly away from the start area 30 in the X-Y plane until it reaches the end of the substrates 102, 104, at which time the flexible substrate 102 is bonded to the carrier substrate 104.

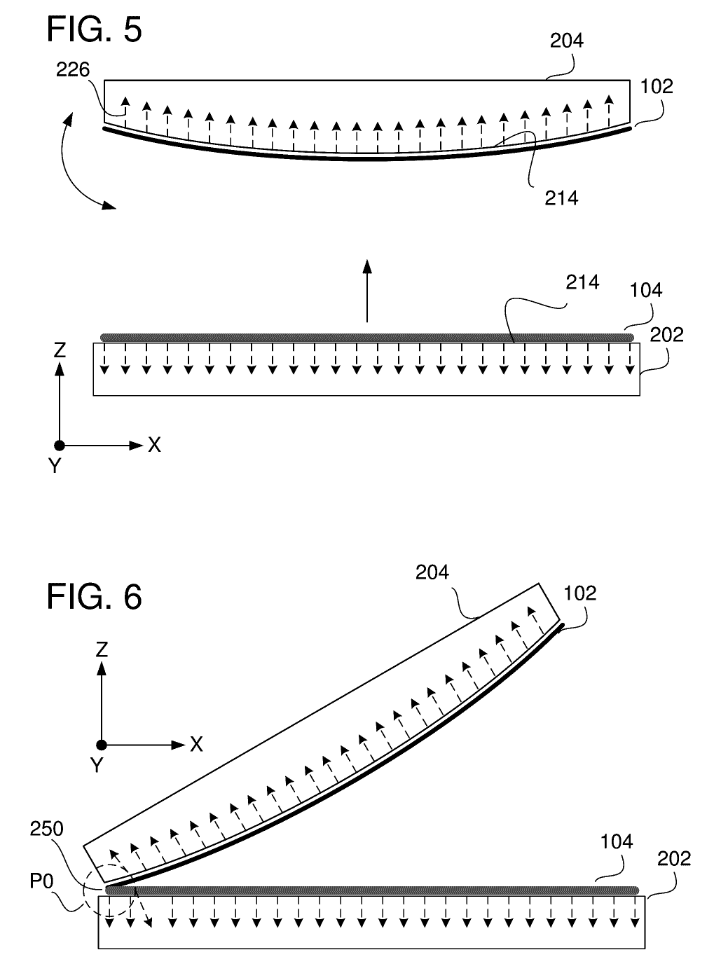

FIG. 4 is a schematic representation of a tool 200 operative to both bond the flexible substrate 102 to the carrier substrate 104, and thereafter, de-bond the flexible substrate 102 from the carrier substrate 104. The tool 200 includes a first plate 202 operative to support the carrier substrate 104, and a second plate 204 operative to support the flexible substrate 102. The relative movement of the first and second plates 202, 204 may be achieved by making both plates movable or at least one plate movable with respect to the other. By way of example, the illustrated embodiment permits the first plate 202 to be movable along the Z-axis (adopting the X, Y, Z axes of FIG. 2) and permits the second plate 204 to be at least rotatable about a line parallel to the Y-axis. In other words, the second plate 204 may pivot about a line parallel to the Y-axis.

The first and second plates 202, 204 are movable with respect to one another via suitable mechanical, electrical, pneumatic, hydraulic, magnetic, and/or other state of the art mechanisms for achieving locomotion. Since the specific details of the particular mechanisms for locomotion are not critical to the implementation of the illustrated embodiments, the discussion herein will be directed to the function of the tool 200. Indeed, skilled artisans would have no difficulty in practicing the illustrated embodiments without burdening the record with unnecessary details concerning well known and available components.

The first plate 202 includes a first bearing surface 212 against which the carrier substrate 104 is supported. The second plate 204 includes a second bearing surface 214 against which the flexible substrate 102 is held and released. Notably, the second bearing surface 214 is substantially cylindrically curved out of the X-Y plane and parallel to the Z-axis. Stated another way, the curvature of the second bearing surface 214 is about a line that is parallel to the Y-axis. Additionally and/or alternatively, the second bearing surface 214 may include a rubber coating (not shown) and/or other intermediate layer between the second plate 204 and the flexible substrate 102 in order to provide some resiliency during the bonding and de-bonding processes.

The first plate 202 may include an array of suction apertures 222 extending through the first bearing surface 212, which are actuated to permit suction fluid to pull the carrier substrate 104 against and hold same to the first bearing surface 212. In accordance with one or more embodiments, the entire array of suction apertures 222 are controlled to provide suction at the same time or to remove suction at the same time. Alternative embodiments may permit that certain of the suction apertures of the array 222 are separately controllable.

The second plate 204 may include an array of suction apertures 224 extending through the second bearing surface 214, the array 224 including a plurality of sets of the suction apertures 226, each set being oriented parallel to the Y-axis and adjacent to one another along the X-axis. In the illustrated example, one set of suction apertures 226 is represented as a line array extending across the second bearing surface 214 parallel to the Y-axis. Skilled artisans will appreciate that alternative embodiments may provide that a given set of apertures 226 includes more than one line array, such as two, three, or more line arrays. Additionally and/or alternatively, the number of line arrays of suction apertures in a given set 226 may vary across the second bearing surface 214. In accordance with one or more embodiments, each set of the suction apertures 226 is separately controllable to provide suction and release suction.

The tool 200 may further include a controller 206 operating to control the movement of the first plate 202, the application and removal of suction through the array of suction apertures 222, the movement of the second plate 204, and the application and removal of suction through each set of suction apertures 226 of the array of suction apertures 224. The arrows from the controller 206 to the noted elements of the tool 200 represent control signaling, sensor measurements, etc. to achieve controllability of such elements by the controller 206. The controller 206 may include one or more microprocessors, memories, sensors, input/output circuits, software, etc. operating in cooperation to achieve the functionality of the tool 200 described herein.

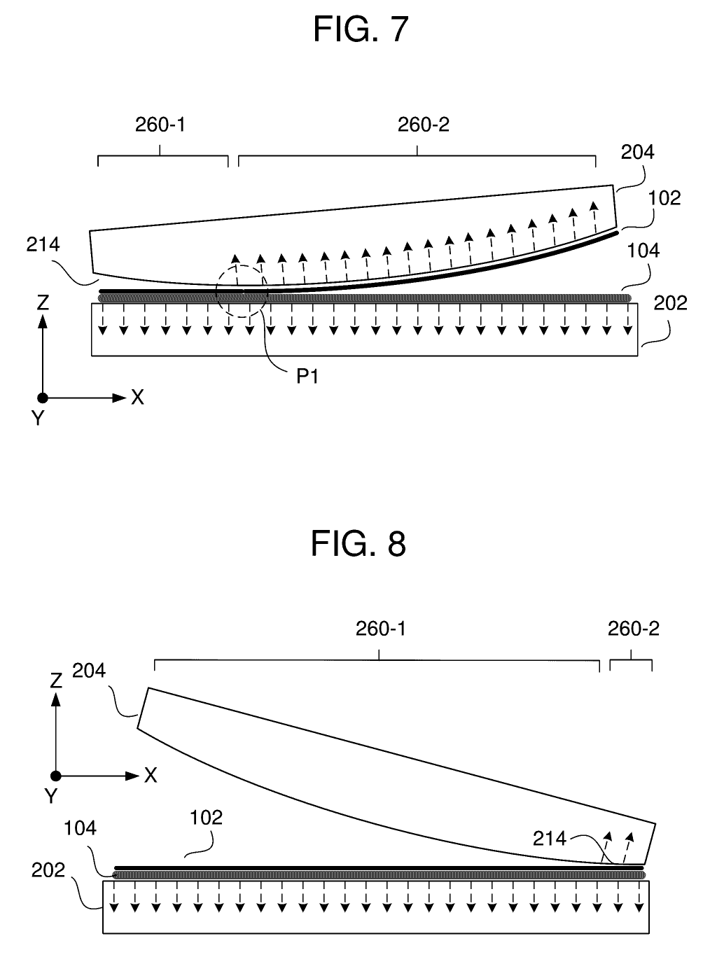

The operation of the tool 200 and the methodologies contemplated herein are illustrated with reference to FIGS. 5-10. Notably, FIGS. 5-10 illustrate two separate process sequences. The first process sequence is a bonding sequence in which the tool 200 is employed to bond the flexible substrate 102 to the carrier substrate 104 as is illustrated by FIGS. 5, 6, 7, 8, 9, and 10, i.e., in sequential order from FIG. 5 through to FIG. 10. The second process sequence is a de-bonding sequence in which the tool 200 is employed to de-bond the flexible substrate 102 from the carrier substrate 104 as is illustrated by FIGS. 10, 9, 8, 7, 6, and 5, i.e., in reverse sequential order from FIG. 10 through to FIG. 5.

With reference to FIG. 5 through to FIG. 10 in sequential order, the bonding process will now be described.

FIG. 5 illustrates a state in which the flexible substrate 102 is held against the second bearing surface 214 of the second plate 204 via activation of all, or substantially all, of the suction apertures of the array 224, which is illustrated by the plurality of dashed arrows directed toward a center of the second plate 204, i.e., the direction of fluid flow produced by the suction action. More particularly, substantially all of the respective sets of suction apertures 226 are activated, where each set of suction apertures 226 is oriented into the page (parallel to the Y-axis) and is represented by one of the dashed arrows. Similarly, the carrier substrate 104 is held against the first bearing surface 212 of the first plate 202 via activation of all or substantially all of the suction apertures of the array 222, which is illustrated by the plurality of dashed arrows directed toward a center of the first 202, i.e., the direction of fluid flow produced by the suction action.

With reference to FIGS. 5 and 6, the controller 206 and the motion mechanism (schematically illustrated by the motion arrows) operate to move the first and second plates 202, 204 relative to one another to locate the flexible substrate 102 in a spaced apart relationship with the carrier substrate 104 along the Z-axis. More particularly, the controller 206 and the motion mechanism operate to move the first plate 202 along the Z-axis away from, and/or toward, the second plate 204 to achieve a desired spaced apart relationship such that the second plate 204 may be rotated (pivoted) into a desired position. As shown in FIG. 6, the controller 206 and the motion mechanism continue to move the first and second plates 202, 204 such that respective elongate portions of the first and second bearing surfaces 212, 214 are urged toward one another to cause corresponding elongate portions of the substrates 102, 104 to contact one another, e.g., along respective first lateral edges thereof at 250. Continued urging of the respective elongate portions of the first and second bearing surfaces 212, 214 toward one another produces a pressure zone, Pi (e.g., an initial pressure zone P0), in which the flexible substrate 102 is biased toward and into contact with the carrier substrate 104. Due to the above-described geometries of the respective first and second plates 202, 204, the pressure zone P0 extends linearly and parallel to the Y-axis. The pressure zone P0 produces an elongate start area (see element 30 of FIG. 3) in which a bond is initiated between the substrates 102, 104 entirely thereacross along the Y-axis.

With reference to FIGS. 6 to 7 in sequence, the controller 206 and the motion mechanism of the tool 200 operate to release a current pressure zone Pi (such as P0) and apply a subsequent pressure zone Pi+1 (such as P1), also extending parallel to the Y-axis. As compared to pressure zone P0, the subsequent pressure zone P1 is indexed (adjacent to) the pressure zone P0 along the X-axis. The indexing of the current pressure zone P0 (which is removed) to the subsequent pressure zone P1 (which is applied) is achieved by way of the controller 206 and the motion mechanism operating to roll the second plate 204 across the first plate 202 in a direction parallel to the X-axis. For purposes of discussion only, the illustrated spacing of the pressure zones P0, P1 along the X-axis is rather large (referring to FIGS. 6 to 7); however, skilled artisans will appreciate that in a practical implementation of the tool 200 the spacing of the pressure zones P0, P1, P2, etc. may be made smaller or larger depending on the exigencies of the application. Due to the geometries of the respective first and second plates 202, 204, and the rolling of the latter over the former, a skilled artisan will appreciate that the illustrated implementation of the tool 200 will result in a continuous (not discrete) indexing of the pressure zones Pi.

Concurrently with the indexing of the pressure zones Pi, the controller 206 and the second plate 204 are operable to release respective portions of the flexible substrate 102 as the sequential pressure zones Pi, i=0, 1, 2, 3 . . . n, are released. Thus, as illustrated in FIG. 7, a respective portion of the flexible substrate 102 (which is bonded to the carrier substrate 104) is no longer held by the second plate 204, namely the portion of the flexible substrate 102 within the section along the X-axis labeled 260-1. Conversely, respective portions of the flexible substrate 102 (which are not yet bonded to the carrier substrate 104) remain held by the second plate 204, namely the portions of the flexible substrate 102 within the section along the X-axis labeled 260-2.

The release of the respective portions of the of the flexible substrate 102 is achieved by way of the controller 206 sequentially deactivating (turning off) adjacent sets of the suction apertures 226 as the corresponding pressure zones Pi are indexed (i.e., as the respective adjacent pressure zones are sequentially released and applied). The deactivation of certain sets of the suction apertures 226 is illustrated by the absence of dashed arrows of fluid flow within the section along the X-axis labeled 260-1. Other sets of suction apertures 226 remain activated (holding the flexible substrate 102 to the bearing surface 214 of the second plate 204), namely the sets of suction apertures 226 within the section along the X-axis labeled 260-2. The sequential deactivation of the adjacent sets of the suction apertures 226 sequentially releases the respective portions of the flexible substrate 102 from the second bearing surface 214 of the second plate 204 in synchronism with the indexing of the pressure zones Pi.

As illustrated in FIGS. 6, 7, and 8 in sequence, the indexing of the pressure zones is repeated for a plurality of the pressures zones Pi, i=0, 1, 2, 3 . . . n, and the simultaneous and sequential release respective portions of the flexible substrate 102 (via deactivation of respective sets of suction apertures 226) is carried out. This action sequentially propagates the bond front (again referring to element 34 of FIG. 3 and the linearly directed vectors extending transversely away from the elongate start area 30 and parallel to the X-axis). The bond propagation continues until the bond front reaches an end of the substrates 102, 104.

As illustrated in FIGS. 9 to 10, the controller 206 and the motion mechanism of the tool 200 operate such that the aforementioned bond front reaches the far lateral edges 252 of the substrates 102, 104, at which point the flexible substrate 102 is completely bonded to the carrier substrate 104. The controller 206 and the motion mechanism of the tool 200 may then move the second plate 204 away from the bonded structure 100 and move the structure 100 to downstream processes and/or destinations (e.g., the above-described conventional sheet manufacturing processes and techniques).

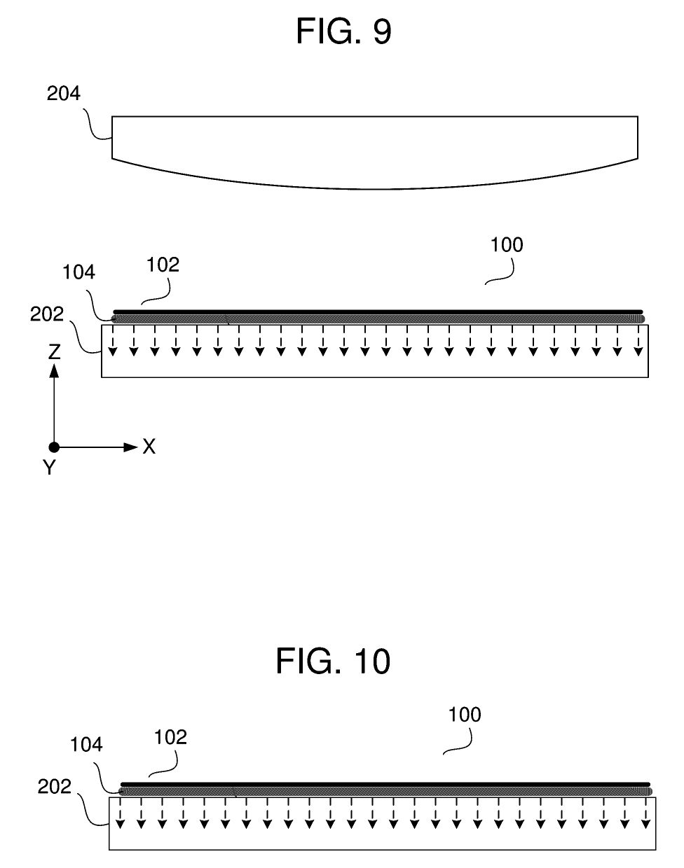

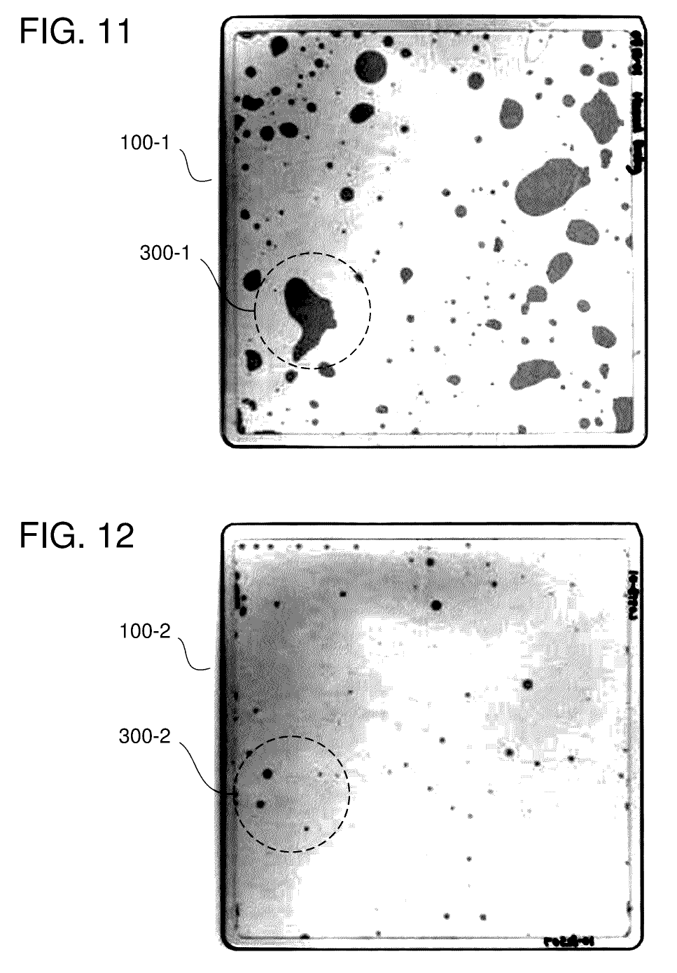

Experimentation was conducted in connection with evaluating the tool 200 and methodologies described above. A carrier substrate 104 formed from glass of 0.7 mm thickness and a flexible substrate also formed from glass of 0.1 mm thickness (ultra-thin) were bonded manually and with an implementation of the tool 200 described herein. FIG. 11 is a graphical illustration of a qualitative result of manually bonding the flexible substrate 102 to the carrier substrate 104 yielding sample 100-1. FIG. 12 is a graphical illustration of a qualitative result of bonding the flexible substrate 102 to the carrier substrate 104 using the tool 200, yielding sample 100-2.

The qualitative measurement as between the samples was related to the amount of air trapped between the two substrates 102, 104 in each case. For the sample 100-1 that was bonded manually (FIG. 11), a bonding area expansion occurred naturally and a substantial amount of air 300-1 was trapped due to the manner in which the bonding front expanded. In contrast, using the bonding tool 200, the bond between the substrates 102, 104 of sample 100-2 was controlled such that the bonding front developed line-by-line, indexing along the X-axis, which resulted in a greatly reduced amount of air 300-2 trapped between the substrates 102, 104. The reduction in the amount of trapped air was on the order of 10:1.

With reference to FIG. 10 through to FIG. 5 in reverse sequential order, the de-bonding process will now be described. Essentially, the specific steps in connection with de-bonding the flexible substrate 102 from the carrier substrate 104 from the status of the bonded structure 100 illustrated in FIG. 10 are the reverse of the steps of the bonding process. The controller 206 and the motion mechanism are operative to move the first and second plates 202, 204 relative to one another, such as in the spaced apart orientation of FIG. 9. With reference to FIGS. 9 to 8 in sequence, the controller 206 and the motion mechanism are operative to locate the second plate 204 relative to the first plate 202 such that an elongate portion of the second bearing surface 214 contacts a corresponding elongate portion of the flexible substrate 102. Simultaneously, the controller 206 commands application of suction through at least one or more of the sets of suction apertures 226 of the second plate 204 proximate to the corresponding elongate portion of the flexible substrate 102 (i.e., the one or more of the sets of suction apertures 226 within section 260-2 along the X-axis).

With reference to FIGS. 8, 7, 6 in sequence, the controller 206 and the motion mechanism are operative to roll the second plate 204 across flexible substrate 102 in an X-direction parallel to the X-axis (opposite to the direction of rolling during bonding) and simultaneously permit sequential application of suction through respective adjacent ones of the sets of suction apertures 226. This rolling action peels the flexible substrate 102 from the carrier substrate 104. Breakage of the flexible substrate 102 may be avoided by minimizing (or eliminating) any variation in bend angles (e.g., increase during peeling) and resultant variation in stress applied thereto. The disclosed tool 200 and methodology for de-bonding ensures consistent bend angle and consistent de-bonding velocity during peeling, which eliminates the aforementioned breakage. Additionally, antistatic ionizing air may be introduced via a slit (not shown) in the first plate 202, where the slit is positioned following the de-bonding direction, which would assist in de-bonding and also prevent re-bonding of the flexible ultrathin and carrier glass due to antistatic force.

As illustrated in FIG. 5, the controller 206 and the motion mechanism are operative to move the second plate 204 away from the first plate 202 after complete de-bonding of the flexible substrate 102 from the carrier substrate 104.

Although the disclosure herein has been described with reference to particular embodiments, it is to be understood that these embodiments are merely illustrative of the principles and applications of the embodiments herein. It is therefore to be understood that numerous modifications may be made to the illustrative embodiments and that other arrangements may be devised without departing from the spirit and scope of the present application.

1. An apparatus, comprising:
a first plate operative to support a carrier substrate formed from a sheet of material, the carrier substrate having a length dimension in an X-axis, a width dimension in a Y-axis, and a thickness dimension in a Z-axis, where the X-axis and Y-axis define an X-Y plane;
a second plate operative to hold and release a flexible substrate formed from a sheet of material, the flexible substrate having a length dimension in the X-axis, a width dimension in the Y-axis, and a thickness dimension in the Z-axis, wherein at least one of: (i) a flexibility of the flexible substrate is substantially more flexible than a flexibility of the carrier substrate, and (ii) the thickness of the flexible substrate is substantially less than a thickness of the carrier substrate;
a motion mechanism operative to move the first and second plates relative to one another, in sequence, to:
(a) locate the flexible substrate in a spaced apart relationship with the carrier substrate along the Z-axis,
(b) apply a pressure zone, P0, in which the flexible substrate is urged toward, and into contact with, the carrier substrate, where the pressure zone P0 extends linearly parallel to the Y-axis to produce an elongate start area in which a bond is initiated between the substrates entirely there across along the Y-axis,
(c) release a current pressure zone Pi and apply a subsequent pressure zone (Pi+1), extending parallel to the Y-axis and indexed adjacent to the current pressure zone Pi along the X-axis, and
(d) repeat action (c) for a plurality of pressures zones Pi, i=0, 1, 2, 3 . . . n, thereby sequentially propagating a bond front having linearly directed vectors extending transversely away from the elongate start area in the X-Y plane substantially parallel to the X-axis, and continuing such propagation until the bond front reaches an end of the substrates at which time the flexible substrate is completely bonded to the carrier substrate.

2. The apparatus of claim 1, wherein the second plate is operable to release respective portions of the flexible substrate as the sequential pressure zones Pi, i=0, 1, 2, 3 . . . n, are released such that the entirely of the flexible substrate is released from the second plate when the bonding is completed.

3. The apparatus of claim 1, wherein:
the first plate includes a first bearing surface against which the carrier substrate is supported;
the second plate includes a second bearing surface against which the flexible substrate is held and released, and the second bearing surface is substantially cylindrically curved out of the X-Y plane and parallel to the Z-axis.

4. The apparatus of claim 3, wherein the motion mechanism is operative to move the second plate relative to the first plate such that corresponding, respective elongate portions of the first and second bearing surfaces are urged toward one another to apply the sequential pressure zones (Pi, i=0, 1, 2, 3, . . . n) in which the flexible substrate is urged toward, and into contact with, the carrier substrate, to produce the elongate start area proximate to respective first edges of the flexible substrate and the carrier substrate and the subsequent propagation of the bond front.

5. The apparatus of claim 4, wherein the motion mechanism is operative to roll the second plate across the first plate in an X-direction parallel to the X-axis in order to index the pressure zones (for i=0, 1, 2, 3 . . . n).

6. The apparatus of claim 3, wherein:
the second plate includes an array of suction apertures extending through the second bearing surface, the array including a plurality of sets of the suction apertures, each set being oriented parallel to the Y-axis and adjacent to one another along the X-axis;
each set of the suction apertures is separately controllable to provide suction and release suction; and
the apparatus is controllable such that adjacent sets of the suction apertures are sequentially turned off as the pressure zones Pi are sequentially released and applied in order to sequentially release respective portions of the flexible substrate from the second bearing surface in synchronism and such that the entirely of the flexible substrate is released from the second plate when the bonding is completed.

7. The apparatus of claim 6, wherein the apparatus is operative to de-bond the flexible substrate from the carrier substrate after complete bonding.

8. The apparatus of claim 7, wherein the motion mechanism is operative to move the first and second plates relative to one another, in sequence, to:
(a) locate the second plate relative to the first plate, which is operable to support the carrier substrate atop which the flexible substrate is completely bonded, such that an elongate portion of the second bearing surface contacts a corresponding elongate portion of the flexible substrate;
(b) permit application of suction through at least one or more of the sets of suction apertures proximate to the corresponding elongate portion of the flexible substrate;
(c) roll the second plate across flexible substrate in an X-direction parallel to the X-axis and simultaneously permit sequential application of suction through respective adjacent ones of the sets of suction apertures in order to peel the flexible substrate from the carrier substrate; and
(d) move the second plate away from the first plate after complete de-bonding of the flexible substrate from the carrier substrate.

9. A method comprising:
(a) providing a first plate operative to support a carrier substrate formed from a sheet of material, the carrier substrate having a length dimension in an X-axis, a width dimension in a Y-axis, and a thickness dimension in a Z-axis, where the X-axis and Y-axis define an X-Y plane;
(b) providing a second plate operative to hold and release a flexible substrate formed from a sheet of material, the flexible substrate having a length dimension in the X-axis, a width dimension in the Y-axis, and a thickness dimension in the Z-axis, wherein at least one of: (i) a flexibility of the flexible substrate is substantially more flexible than a flexibility of the carrier substrate, and (ii) the thickness of the flexible substrate is substantially less than a thickness of the carrier substrate;
(c) locating the flexible substrate in a spaced apart relationship with the carrier substrate along the Z-axis, via movement of the first plate relative to the second plate;
(d) applying a pressure zone, P0, in which the flexible substrate is urged toward, and into contact with, the carrier substrate, via movement of the first plate relative to the second plate, where the pressure zone P0 extends linearly parallel to the Y-axis to produce an elongate start area in which a bond is initiated between the substrates entirely there across along the Y-axis;
(e) releasing a current pressure zone Pi and applying a subsequent pressure zone (Pi+1), extending parallel to the Y-axis and indexed adjacent to the current pressure zone Pi along the X-axis, via movement of the first plate relative to the second plate; and
(f) repeating action (e), via movement of the first plate relative to the second plate, for a plurality of pressures zones Pi, i=0, 1, 2, 3 . . . n, thereby sequentially propagating a bond front having linearly directed vectors extending transversely away from the elongate start area in the X-Y plane substantially parallel to the X-axis, and continuing such propagation until the bond front reaches an end of the substrates at which time the flexible substrate is completely bonded to the carrier substrate.

10. The method of claim 9, further comprising releasing respective portions of the flexible substrate from the second plate as the sequential pressure zones Pi, i=0, 1, 2, 3 . . . n, are released such that the entirely of the flexible substrate is released from the second plate when the bonding is completed.

11. The method of claim 9, wherein:
the first plate includes a first bearing surface against which the carrier substrate is supported;
the second plate includes a second bearing surface against which the flexible substrate is held and released, and the second bearing surface is substantially cylindrically curved out of the X-Y plane and parallel to the Z-axis.

12. The method of claim 11, further comprising moving the second plate relative to the first plate such that corresponding, respective elongate portions of the first and second bearing surfaces are urged toward one another to apply the sequential pressure zones (Pi, i=0, 1, 2, 3, . . . n) in which the flexible substrate is urged toward, and into contact with, the carrier substrate, to produce the elongate start area proximate to respective first edges of the flexible substrate and the carrier substrate and the subsequent propagation of the bond front.

13. The method of claim 12, further comprising rolling the second plate across the first plate in an X-direction parallel to the X-axis in order to index the pressure zones (for i=0, 1, 2, 3 . . . n).

14. The method of claim 11, wherein:
the second plate includes an array of suction apertures extending through the second bearing surface, the array including a plurality of sets of the suction apertures, each set being oriented parallel to the Y-axis and adjacent to one another along the X-axis;
each set of the suction apertures is separately controlled to provide suction and release suction; and
the method further comprises controlling the provision and release of suction such that adjacent sets of the suction apertures are sequentially turned off as the pressure zones Pi are sequentially released and applied in order to sequentially release respective portions of the flexible substrate from the second bearing surface in synchronism and such that the entirely of the flexible substrate is released from the second plate when the bonding is completed.

15. The method of claim 14, further comprising de-bonding the flexible substrate from the carrier substrate after complete bonding.

16. The method of claim 15, further comprising moving the first and second plates relative to one another, in sequence, to:
(a) locate the second plate relative to the first plate, which is operable to support the carrier substrate atop which the flexible substrate is completely bonded, such that an elongate portion of the second bearing surface contacts a corresponding elongate portion of the flexible substrate;
(b) permit application of suction through at least one or more of the sets of suction apertures proximate to the corresponding elongate portion of the flexible substrate;
(c) roll the second plate across flexible substrate in an X-direction parallel to the X-axis and simultaneously permit sequential application of suction through respective adjacent ones of the sets of suction apertures in order to peel the flexible substrate from the carrier substrate; and
(d) move the second plate away from the first plate after complete de-bonding of the flexible substrate from the carrier substrate.

17. The method of claim 9, wherein the flexible substrate is formed from glass.

18. The method of claim 17, wherein the flexible substrate has a thickness of one of: (i) from about 50 um to about 300 um, and (ii) from about 100 um to about 200 um.

19. The method of claim 18, wherein the flexible substrate has at least one of: a density of about 2.3-2.5 g/cc, a Young's Modulus of about 70-80 GPa; a Poisson Ratio of about 0.20-0.25, and a minimum bend radius of about 185-370 mm.

20. The method of claim 9, wherein the carrier substrate is formed from glass.

21. The method of claim 20, wherein the carrier substrate has a thickness of one of at least about 400 to about 1000 um.
